(19) United States
(12) Patent Application Publication
(10) Pub. No.: US 2012/0092196 A1
(43) Pub. Date: Apr. 19, 2012

(54) METHOD FOR INPUTTING TEXT USING NUMERIC KEYPAD

(75) Inventors: Hong WANG, Suzhou (CN); Jiming WU, Suzhou (CN)

(73) Assignee: SUZHOU UNIVERSITY, Suzhou (CN)

(21) Appl. No.: 13/243,285

(22) Filed: Sep. 23, 2011

(30) Foreign Application Priority Data
Oct. 15, 2010 (CN) 201010507627.8

(51) Int. Cl. H03M 11/00

(52) U.S. Cl. 341/28

(57) ABSTRACT

A method for inputting text using the keys of 0-9 of a numeric keypad. The code length of digital encoding may be from 4 to 5 bits. For Chinese-characters, the total number of strokes expressed by two figures may correspond to the first two bits, the first three stroke codes may correspond to the third to the fifth bits, respectively, and inputting the termination code when the total code length is less than 5 bits. For letters, figures, and symbols, two bits express the serial number, the third bit is an identification code, and the fourth bit is the termination code, Chinese-characters and other characters may be inputted with the same input method without switching the input state. The probability of repeated codes is low. The methods can be used by various kinds of input devices with numeric keys.

### TECHNICAL FIELD

The present disclosure relates to a method for inputting text into a processing unit with an input device, and more particularly to a method for inputting Chinese-characters, letters, figures, and other symbols using a numeric keypad with keys of 0-9.

### BACKGROUND

Following the expansion of the application field of computer technology, the demands for text input are on the rise. Text input, figures, letters, Chinese-characters, punctuation marks, operators, and other printable characters, which are generally called text, are inputted by keyboard. Generally, various kinds of text appear crosswise in the contents inputted by keyboard.

In many situations, input devices only have keypads that comprise numeric keys of 0-9, *, and #, such as, for example, a keyboard of a mobile phone. There are also keypads on, for example, ATMs, etc. Moreover, the virtual keyboard set on a device with a touch screen may also have a keypad. Because many keypads have only 12 to 16 keys, a method switching the input state is used in order to input various texts in existing technology.

For example, for a mobile phone, the input state is switched between figures, capital letters, and lower case letters, PINYIN input methods, stroke input methods, and punctuation mark input states, by clicking a key (such as #) repeatedly. The contents are inputted by using the keyboard according to the rule for using each input state. For example, 3 or 4 letters of the 26-letter alphabet are arranged on each key when using the capital letter input state, and the letter is inputted by clicking a key.

Many PINYIN combinations may be obtained by the combinations of letters set on keys with the PINYIN input method, where Chinese-characters are inputted by switching the PINYIN combinations. So, if a capital letter needs to be inputted in the process of inputting Chinese-characters with the PINYIN input method, a user must click the key of “#” four times in order to switch to the capital letter input state, then click a key several times in order to input the letter according to the location where the letter is set, then click the key of “#” twice to turn to the PINYIN input state after the input of the letter. Thus, 7 to 11 clicks are needed in order to input a capital letter between two Chinese-characters.

The same problem also exists in the crosswise input of other different types of letters, figures, or symbols. If the input device supports other characters simultaneously, such as, for example, Japanese or Russian, etc., the number of key clicks increases when switching, and, if switching occurs frequently between different input methods, a user may get confused and input error will occur.

Another problem is that, due to several letters sharing one numeric key, when inputting letters or Chinese-characters with the PINYIN input method, a user often clicks the same key repeatedly. The switching key is also pressed repeatedly when switching the input state. Clicking the same key repeatedly causes a decrease in input speed and an increase in input error for the soft keyboard used on a device such as a touch screen.

### SUMMARY

This disclosure provides methods for inputting text using one or more numeric keypads. The input of capital letters, lower-case letters, Chinese-characters, figures, and symbols is realized without switching input method. Meanwhile, situations requiring clicking the same key repeatedly are decreased as far as possible in order to adapt to using a soft keyboard.

### DETAILED DESCRIPTION

One embodiment provides a method for inputting'text using a numeric keypad, the method comprising using the keys of 0-9 of a numeric keypad, inputting the figure of digital encoding that corresponds to the text by pressing the key directly, and realizing the input of the text; the code length of digital encoding is 4 to 5 bits, and the methods for coding digital encoding are:

(1) Chinese-characters: a total number of strokes expressed by two figures corresponds to the first two bits; according to the writing order, the first stroke code, the second stroke code, and the third stroke code of a Chinese-character correspond to the third to the fifth bits respectively, inputting one stroke code of the Chinese-character at least, and inputting the termination code when the total code length less than 5 bits.

The correspondences between said stroke code and stroke are:

“0”—horizontal line (writing from left to right) or rising stroke (from left to right);

“1”—vertical line (writing from top to bottom);

“2”—left-falling stroke (right-to-left diagonal curve);

“3”—dot (normally “slanting” to the left) or right-failing stroke (left-to-right diagonal curve);

“4”—turning stroke (typically like a 90° or a 45° turn).

(2) English Letters: a serial number of the letter expressed by 2 figures corresponds to the first two bits, the third bit of a capital letter corresponds to a key of “6”, the third bit of a lower-case letter corresponds to a key of “7”, and the fourth bit is the termination code.

(3) Figures and Operators: setting its marshalling sequence, a serial number expressed by 2 figures corresponds to the first two bits, the third bit corresponds to a key of “8”, and the fourth bit is the termination code.

(4) Punctuation Marks: setting its marshalling sequence, a serial number expressed by 2 figures corresponds to the first two bits, the third bit corresponds to a key of “9”, and the fourth bit is a termination code.

In embodiments, a method using two figures to express the stroke of a Chinese-character or the serial number of another character may be used so the code lengths are orderly. The stroke code of a Chinese-character may be misaligned with the code of other characters, so Chinese-characters or other characters may be distinguished by the third code. Computer software can easily process it using the termination code to express the end of input when the code length less than 5 bits. Thus, problems of the existing input method using a numeral keyboard where the code length is not uniform and the longest code length is too long have been solved.

In embodiments, the termination codes correspond to the key of “5”. According to this embodiment, the termination code is different from the preceding code, and is suitable for the input method using a virtual keyboard used on devices having a touch screen.

In embodiments, the termination code of Chinese-characters lies on the key of “5”, the termination code of capital letter lies on the key of “6”, the termination code of lower-case letters lies on the key of “7”, the termination code of figures and operators lies on the key of “8”, and the termination code of punctuation marks lies on the key of “9”. Because the termination code and the type code of character are the same in this embodiment, it is easy to press the keys. Thus, the input speed is increased when using an entity keyboard.

In embodiments, the marshalling sequence of figures and operators is “1 2 3 4 5 6 7 8 9 0 + − * / = < > [ ]{ } ( ) $ % &”, which corresponds to the serial number of “01”to “26” successively. The marshalling sequence of punctuation marks is “blank space , . [symbol] ? ! : ; “ ‘ ′ @ \ . . . — ˜ |”, which corresponds to the serial number of “01” to “17” successively. Also, other orders may be used according to the figure, operator, or punctuation mark that is inputted and they still fall within the scope of this disclosure.

In embodiments, if there is repeated code, a user can turn a page with the keys of “*” and “#” of the keyboard of a mobile phone or the keys of “+” and “−” of other keypads and select a character to input with the numeric key corresponding to the ten Chinese-characters shown on each screen.

Embodiments have the following effects compared with the background technologies:

1. In embodiments, by setting the stroke code of a Chinese-character and the identification code of a character on a different numeric key, the whole text that consists of Chinese-characters and other characters can be inputted with the same input method without switching the input state, and, thus, can be used by various kinds of input devices with numeric keys.

2. Embodiments used to input a Chinese-character, wherein the combination of total number of strokes and the first three stroke codes, together with the reasonable distribution of stroke keys, may have a maximum number of 22 repeated codes of Chinese-characters in the GB2312 character set by numerical keyboard with the code length of 5 bits. Seeking a word by turning pages constantly, as is done with the PINYIN input method, is not needed. Thus, the input speed of Chinese-characters is fast.

3. Because the termination code of embodiments is set to the input of text having a code length less than 5 bits, the input of other characters can be expanded as needed, such as, for example, using 61, 62, or 63 to express other character sets on the third and the fourth bit. Thereby, characters such as, for example, Greek letters or Russian letters, etc. can be inputted synchronously without switching the input method.

4. In embodiments, the probability of the same figure appearing successively in a character code is low. Thus, when applied to various kinds of virtual keyboards, such as those used in devices having a touch screen, the input speed is increased greatly and misoperation is avoided.

### EXAMPLES

The following examples are for illustration purposes only and are not intended as limitations of the disclosure.

### Example

A method for inputting text using a numeric keypad, wherein: using the keys of 0-9 of a numeric keypad, inputting the figure of digital encoding that corresponds to the text by pressing the key directly, and realizing the input of the text; the code length of digital encoding is 4 or 5 bits, the methods for coding digital encoding are:

(1) Chinese-characters: a total number of strokes expressed by two figures corresponds to the first two bits, according to the writing order, the first stroke code, the second stroke code, and the third stroke code of Chinese-character correspond to the third to the fifth bits respectively, inputting one stroke code of Chinese-character at least, and inputting the termination code when the total code length less than 5.

The correspondences between the stroke code and the stroke are:

“0”—horizontal line (writing from left to right) or rising stroke (from left to right);

“1”—vertical line (writing from top to bottom);

“2”—left-falling stroke (right-to-left diagonal curve);

“3”—dot (normally “slanting” to the left) or right-falling stroke (left-to-right diagonal curve);

“4”—turning stroke (typically like a 90° or a 45° turn).

(2) English letters: a serial number of the letter expressed by 2 figures corresponds to the first two bits, the third bit of a capital letter corresponds to a key of “6”, the third bit of a lower-case letter corresponds to a key of “7”, and the fourth bit is the termination code.

(3) Figures and Operators: setting its marshalling sequence, serial number expressed by 2 figures corresponds to the first two bits, the third bit corresponds to a key of “8”, and the fourth bit is the termination code. In this example, the marshalling sequence of figures and operators is “1 2 3 4 5 6 7 8 9 0 + − * / < > [ ] { } ( ) $ % &”, which corresponds to the serial number of “01” to “26” successively.

(4) Punctuation Mark: setting its marshalling sequence, a serial number expressed by 2 figures corresponds to the first two bits, the third bit corresponds to a key of “9”, and the fourth bit is the termination code. In this example, the marshalling sequence of punctuation marks is “blank space , . [symbol] ? ! : ; “ ‘ ′ @ \ . . . — ˜ |”, which corresponds to the serial number of “01” to “17” successively.

When used for a virtual keyboard, all termination codes correspond to a key of “5”.

When used for a general numeric keyboard, the termination code for a Chinese-character lies on a key of “5”, the termination code of a capital letter lies on a key of “6”, the termination code of lower-case letters lies on a key of “7”, the termination code of a figure or operator lies on a key of “8”, and the termination code of a punctuation mark lies on a key of “9”.

Examples of input code of some texts by using different termination codes are described below :
—0105 (the total number of strokes expressed by 01 is one, the key of “0” corresponds to a horizontal line, and the key of “5” corresponds to the termination code); there is no repeated code character.
[symbol] 02235 (the total number of strokes expressed by 02 is 2, the key of “2” corresponds to the left-falling stroke, of the key of “3” corresponds to the right-falling stroke, and the key of “5” corresponds to the termination code); the two repeated code characters are: [symbol] , and [symbol] ; and there are three characters altogether.

Most repeated codes appear when the total number of strokes is 12. Therein, the most repeated codes appear when the input code is 12010 (disregarding the repeated code caused by brevity code), such that the total number of strokes is 12, and the first three strokes are a horizontal line, a vertical line, and a horizontal line (or rising stroke); there are 22 Chinese-characters, as follows:

[symbol]

[symbol]

[symbol]

[symbol]

[symbol]

In embodiments, a user may need to switch screens twice at most. In most cases, a user may need to switch screens once or not at all when the Chinese-character is inputted.

Below are examples of inputting characters:

A, 0166; G, 0766; a, 0177; x, 2477;

2, 0288; 0, 1088; *, 1388; =, 1588;

ₒ , 0399; !, 0699; (, 2299;), 2399.

In embodiments, various letters, figures, and symbols can be inputted using a 4-bit numeric code, and various kinds of Chinese-characters may be inputted using a 4- to 5-bit numeric code without switching the input method. Even after adding the turning code and the selecting code, the Chinese-character having the most keystrokes may be inputted with 8 keystrokes.

In addition, as needed, the input of other characters can be added, and the number of repeated codes will not increase.

For example, using the 5-key type-in method to input Russian characters, the first two keys are a serial number of the letter, the third and the fourth keys use 61 as Russian identification code, and the fifth key uses 6 as the termination code of the capital letter and uses 7 as the termination code of lower-case letter.

Examples are shown below:

[symbol] , 02616; [symbol] , 07616; [symbol] , 02617; [symbol] , 07617.

In embodiments, text can be inputted conveniently by numeral keyboard without switching the input method, the keystrokes may be few, the repeated codes may be few, and embodiments are especially fit for use without a large keyboard.

1. A method for inputting text using a numeric keypad, the method comprising
using keys of 0-9 of a numeric keypad;
inputting a figure of digital encoding that corresponds to the text by pressing a key directly; and
realizing the input of text,
wherein a code length of digital encoding is 4 to 5, and
methods for coding the digital encoding are:
(1) Chinese-characters: a total number of strokes expressed by two figures corresponds to the first two bits; according to a writing order, a first stroke code, a second stroke code, and a third stroke code of a Chinese-character correspond to the third to the fifth bits respectively, inputting one stroke code of the Chinese-character at least, and inputting a termination code when the total code length is less than 5 bits, where
the correspondences between said stroke code and stroke are:
“0” —horizontal line or rising stroke;
“1”—vertical line;
“2” left-falling stroke;
“3” —dot or right-falling stroke;
“4” —turning stroke;
(2) English letter, letters: a serial number of a letter expressed by 2 figures corresponds to the first two bits, the third bit of a capital letter corresponds to a key of “6”, the third bit of a lower-case letter corresponds to a key of “7”, and the fourth bit is a termination code;
(3) figures and operators: setting its marshalling sequence, a serial number expressed by 2 figures corresponds to the first two bits, the third bit corresponds to a key of “8”, and the fourth bit is a termination code;
(4) punctuation marks: setting its marshalling sequence, a serial number expressed by 2 figures corresponds to the first two bits, the third bit corresponds to a key of “9”, and the fourth bit is a termination code.

2. The method for inputting text using a numeric keypad according to claim 1, wherein all the termination codes correspond to a key of “5”.

3. The method for inputting text using a numeric keypad according to claim 1, wherein
the termination code for Chinese-characters lies on a key of “5”,
the termination code for capital letters lies on a key of “6”,
the termination code for lower-case letters lies on a key of “7”,
the termination code for figures and operators lies on a key of “8”, and
the termination code for punctuation marks lies on a key of “9”.

4. The method for inputting text using a numeric keypad according to claim 1, wherein the marshalling sequence of the figures and operators is “1 2 3 4 5 6 7 8 9 0 + − * / = < > [ ] { } ( ) $ % &” , which corresponds to a serial number of “01” to “26” successively.

5. The method for inputting text using a numeric keypad according to claim 1, wherein the marshalling sequence for the punctuation mark is “blank space, . □ □ □ : ; “ ‘ ′ @ \ . . . — □ |”, which corresponds to a serial number of “01” to “17” successively.
